(19) United States
(12) Patent Application Publication
(10) Pub. No.: US 2024/0288178 A1
(43) Pub. Date: Aug. 29, 2024

(54) THERMOELECTRIC BATTERY SYSTEM AND METHODS THEREOF

(71) Applicant: VOLTAIR POWER INC., Oyster Bay, NY (US)

(72) Inventor: Jerritt L. Gluck, Oyster Bay, NY (US)

(21) Appl. No.: 18/569,902

(22) PCT Filed: Jun. 15, 2022
(86) PCT No.: PCT/US2022/033536

§ 371 Date: Dec. 13, 2023

Related U.S. Application Data
(60) Provisional application No. 63/210,970, filed on Jun. 15, 2021.

(51) Int. Cl. F24D 11/02; F24D 101/60; F24H 4/04; H10N 10/13

(52) U.S. Cl. CPC F24D 11/0214; F24H 4/04; H10N 10/13; F24D 2101/60; F24D 2200/123; F24D 2220/06; F24D 2220/10; F24H 2240/01

(57) ABSTRACT

A thermoelectric battery system includes a heat pump configured to generate heat. A buffer tank is thermally coupled to the heat pump and configured to store the generated heat in boiler water. A thermal battery is thermally coupled to the buffer tank. The thermal battery provides at least one of hot water for domestic use, hydro-heating, or hydro-cooling. The first thermal battery includes: an inner tank configured to contain a portion of boiler water and an outer tank containing a phase change material. The outer tank surrounds the inner tank and is separated therefrom by a thermally conductive wall. The outer tank is configured to supply heat to the inner tank. A heat exchanger disposed in the inner tank is configured to heat potable water flowing therethrough to enable potable water to be heated by boiler water to produce domestic hot water.

### PRIORITY

This application claims the benefit of and priority to U.S. Provisional Application No. 63/210,970 filed Jun. 15, 2021, the entire disclosure of which is hereby incorporated by reference.

### BACKGROUND

### Technical Field

The present disclosure relates to boilers and energy storage systems, and, in particular, relates to a thermoelectric battery system utilizing phase change materials and thermoelectric converters to provide domestic hot water, hydronic heating and/or hydronic cooling.

### Description of Related Art

To heat water for domestic use or hydronic heating and cooling environment control systems, water is often heated by conventional hot water systems including large boiler tank systems, direct “instant” tankless heaters, indirect boiler systems, solar water heaters and the like. Where large amounts of domestic hot water are needed, such as in apartment complexes, boiler tanks holding hundreds of gallons of water are used but which fill a large volume of space in a building. These systems typically operate by raising or maintaining hot water between 115° F. and 140° F. In large tanks, the water can have an uneven temperature distribution which may degrade the performance and longevity of the boiler tanks. Many of these systems are also only able to provide hot water for short periods of time or may become inoperable during a power failure. A power failure can cause hydronic heating and cooling systems to fail, and with no other means to heat or cool a building, or to provide hot water, building occupants can be subject to harsh weather conditions.

Similarly, as more energy is obtained from renewable energy sources, fluctuations in the availability of electrical power will become more common. For example, solar arrays cannot produce sufficient power at night since there is no sunlight, which is more pronounced in the winter when days are shorter, and nights are longer than at other times of the year. In another example, wind turbines produce more electricity at night since wind is typically stronger at night than during the day, leading to an imbalance between peak production from the wind turbines and peak demand for electricity during the day. Conventional thermal storage systems are not adapted to bridging the gap between peak power production and peak demand nor are the conventional systems able to sufficiently operate during a power failure.

### SUMMARY

To the extent consistent, any of the aspects detailed herein may be used in conjunction with any or all of the other aspects detailed herein.

An embodiment of this disclosure relates to a thermoelectric battery configured to provide at least one of hot water for domestic use, hydro-heating or hydro-cooling. The thermoelectric battery includes an inner tank configured to contain boiler water for storing and providing heat; an outer tank surrounding the inner tank and separated therefrom by a thermally conductive wall, the outer tank configured to contain a phase-change material to supply heat to the inner tank; a heat exchanger disposed in the inner tank configured to enable domestic water to flow therethrough to enable potable water to be heated by the boiler water. The thermoelectric battery includes an electric battery coupled to a thermoelectric converter; the thermoelectric converter configured to convert heat stored in the inner tank into electricity to be stored by the electric battery.

In an aspect, the thermoelectric converter may include at least one thermopile.

In aspects, the electric battery may be configured to provide backup power to at least one of a pump, an appliance, a light fixture, or a fan.

In aspects, the electric battery may include at least one of lithium ion, nickel-cadmium, zinc-air battery, or nickel metal hydride.

In aspects, the heat exchanger further may include a plurality of coils disposed in the inner tank configured to circulate the potable water therethrough.

In aspects, the plurality of coils define a high coil surface area to boiler water ratio.

In some aspects, the plurality of coils are disposed only in the inner tank of the thermal battery.

In further aspects, the plurality of coils disposed in the inner tank are helical coils.

In aspects, the inner tank is further configured as a reverse indirect water heater tank.

In aspects, the thermoelectric battery may include an insulative jacket configured to cover the outer tank to insulate the outer and inner tanks. The insulative jacket may include at least one of closed cell foam, open cell foam, fiberglass, mineral wool, or composite insulation.

In aspects, the outer tank may be configured to operably increase or maintain the boiler water contained in the inner tank between a temperature from about 125° F. to about 175° F.

In aspects, the outer tank is further configured to absorb excess heat from the inner tank.

In aspects, the thermally conductive wall may include at least one of copper, aluminum, stainless steel, or brass.

In aspects, the phase-change material may include at least one of paraffin wax, non-paraffin organic material, salt hydrates, or ice.

Another embodiment of this disclosure provides a thermo-electric battery system including a first heat pump configured to generate heat; a first buffer tank thermally coupled to the first heat pump, the first buffer tank configured to store the generated heat in boiler water; a first thermal battery thermally coupled to the first buffer tank, the first thermal battery configured to provide at least one of hot water for domestic use, hydro-heating, or hydro-cooling. The first thermal battery includes: an inner tank configured to contain a first portion of the boiler water for storing and providing heat; an outer tank containing a phase change material, the outer tank surrounding the inner tank and separated therefrom by a thermally conductive wall, the outer tank configured to supply heat to the inner tank; and a heat exchanger disposed in the inner tank configured to enable domestic water to flow therethrough to enable the domestic water to be heated by the boiler water. The system also includes an electric battery electrically coupled to a thermoelectric converter; the thermoelectric converter being configured to convert heat in the first thermal battery into electricity. The system also includes a pump configured to supply water to the heat exchanger and pump the water to a building for domestic usc.

In aspects, the first thermal battery may include an insulative jacket configured to cover the outer tank to insulate the outer and inner tanks.

In other aspects, the phase-change material may include at least one of paraffin wax, non-paraffin organic material, salt hydrates, or ice.

In some aspects, the electric battery may be configured to provide backup power to the pump.

In additional aspects, the first heat pump may include a first compressor having a first thermal circuit configured to supply heat to a first refrigerant.

In yet other aspects, the first thermal circuit may be configured to thermally couple the first compressor and the first buffer tank to supply heat to the first buffer tank.

In aspects, the first heat pump further may include a second compressor may include a second thermal circuit configured to transfer heat from the first refrigerant to a second refrigerant of a second thermal circuit.

In alternative aspects, the first compressor may be thermally coupled to the second compressor via the first thermal circuit and the first buffer tank may be coupled to the first compressor via the second thermal circuit of the second compressor.

In more aspects, the first compressor may be configured to be located outdoors and the second compressor may be configured to be located indoors.

In aspects, the thermoelectric battery system may include a plurality of buffer tanks. The plurality of buffer tanks may include the first buffer tank and a second buffer tank, wherein each buffer tank of the plurality of buffer tanks are thermally coupled in series.

In aspects, each thermal battery may be thermally coupled in series with the plurality of buffer tanks.

In aspects, each thermal battery of the plurality of thermal batteries may be independently operable.

In further aspects, at least one thermal battery of the plurality of thermal batteries may be configured to supply domestic hot water. At least one thermal battery may be configured to provide hydro-heating or hydro-cooling.

In aspects, the thermal battery may be configured to operably increase or maintain the boiler water contained in the inner tank between a temperature from about 135° F. to about 175° F.

In other aspects, the first buffer tank may be configured to provide heat to the thermal battery to enable the thermal battery to operably maintain or increase the temperature of the boiler water.

In some aspects, the at least one thermal battery that is configured to provide hydro-heating or hydro-cooling may be connected to at least one of: a radiator system configured to radiate heat into a building; or a hydro-cooling device.

In aspects, the heat exchanger may be configured to heat the domestic water to between about 110° F. to about 135° F.

In aspects, the thermally conductive wall separating the inner tank and the outer tank may substantially include copper.

In aspects, the first heat pump is connected to the first buffer tank, or the first buffer tank is connected to the first thermal battery by reverse return piping or piping including balancing valves.

This disclosure also provides a method for providing domestic hot water. The method includes generating heat via a first heat pump configured to convert electrical energy into heat; storing the generated heat in a fluid in a first buffer tank; transferring the generated heat from the first buffer tank to a thermal battery via the fluid in the first buffer tank. The thermal battery may include: an inner tank configured to contain boiler water for storing a first portion of the generated heat therein; an outer tank surrounding the inner tank and separated therefrom by a thermally conductive wall, the outer tank configured to contain a phase change material for storing a second portion of the generated heat therein; and a heat exchanger disposed in the inner tank. The method includes pumping potable water through the heat exchanger via a pump and heating the potable water to produce domestic hot water.

In aspects, the method may include converting thermal energy in the thermal battery into electrical energy via a thermoelectric converter. The method may further include powering the pump via the electrical energy.

In other aspects, the method may include heating the boiler water in the inner tank via heat stored in the phase change material stored in the outer tank.

In some aspects, the method may include maintaining the boiler water between about 135° F. to about 175° F.

Another embodiment of this disclosure provides a method for providing domestic hot water via a thermoelectric battery may include an inner tank. The method includes enabling potable water to flow through coils of the heat exchanger; heating the coils via boiler water stored in the inner tank to heat the potable water in the heat exchanger and heating the boiler water via heat stored in a phase change material stored in the outer tank.

In aspects, the method may include generating electrical energy by converting thermal energy stored in at least one of the boiler water of the inner tank or the phase change material of the outer tank.

In another aspect, the method may include powering a pump via the generated electrical energy.

In some aspects, the method may include supplying thermal energy to at least one of the boiler water or the phase change material via a heat pump configured to convert electrical energy from a source of electricity into thermal energy.

### BRIEF DESCRIPTION OF THE DRAWINGS

The above and other aspects and features of the present disclosure will become more apparent in view of the following detailed description when taken in conjunction with the accompanying drawings wherein like reference numerals identify similar or identical elements.

FIG. 1 is a simplified block diagram of a thermoelectric battery system in accordance with an embodiment of this disclosure;

FIG. 2 is a schematic diagram of the thermoelectric battery system of FIG. 1;

FIG. 3 is a diagram of the thermal battery of the system of FIG. 2;

FIG. 4 is a perspective, sectional view of the thermal battery of FIG. 3;

FIG. 5 is a diagram of a method for providing domestic hot water via a thermoelectric battery system, in accordance with another embodiment of this disclosure;

FIG. 6 is a diagram of a method for heating water via a thermal battery, in accordance with an embodiment of this disclosure; and

FIG. 7 is a diagram of a method for heating water via a boiler, in accordance with an embodiment of this disclosure.

### DETAILED DESCRIPTION

This disclosure provides a thermoelectric battery system configured to provide domestic hot water, hydronic heating or cooling, and/or backup electrical power. The thermoelectric energy storage and distribution system generally operates by storing energy from a source of electrical energy (e.g., a power grid, solar panel, wind turbine) in the form of thermal energy in a thermal battery. The stored thermal energy is used to heat domestic potable water as well as heat water for use in a heating system (e.g., hydronic heating, floor heating, panel/baseboard heating, etc.).

The thermoelectric battery system is configured to balance the supply of energy from a renewable energy source such as, for example, solar power generation farms or wind turbines, and the demand for the energy generated by the renewable energy source which often do not coincide. Since the thermoelectric battery system can generate and store thermal energy for later use (e.g., for use hours or days later) during demand times or when the renewable energy source cannot provide sufficient power, the energy load on a utility grid is reduced since the thermoelectric battery system stores some of the electrical energy generated when available but needed as thermal energy. The thermoelectric battery system includes natural system heat loss but otherwise is able to store a large amount of electrical energy as thermal energy. The thermoelectric battery system thus helps distribute the demand on a utility grid while also saving users money since less power from a utility will be purchased during peak power demand times.

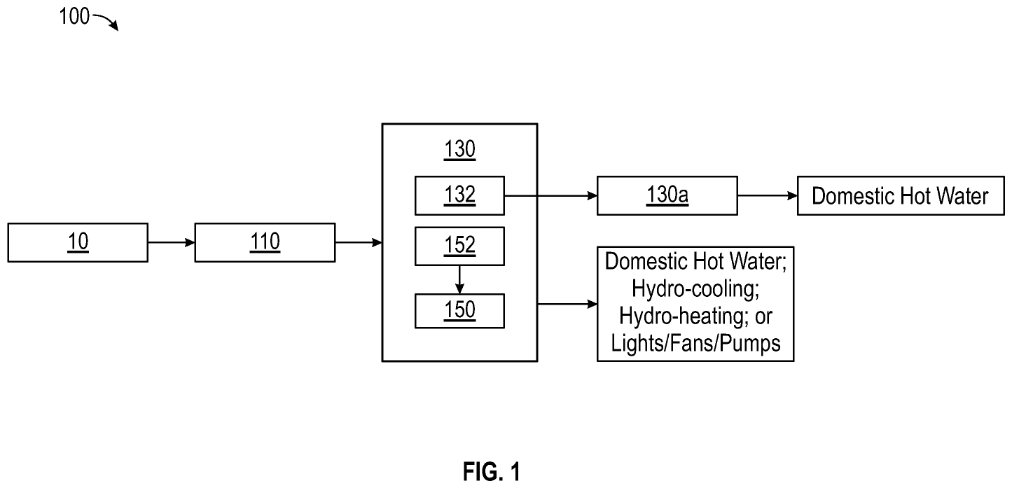

With reference to FIG. 1, a thermoelectric battery system 100 includes a heat pump 110 thermally coupled to one or more thermal batteries 130. The thermal battery 130 includes a boiler 132 and may include a thermoelectric converter 152 coupled to an electric battery 150. Thus, the thermal battery 130 is a thermoelectric battery. The heat pump 110 is configured to receive power from an electrical source 10 (e.g., a utility grid, a solar panel, a wind turbine, thermal generator, wave generator, etc.) and generate heat. Thus, the heat pump 110 converts electrical energy into thermal energy. The heat produced by the heat pump 110 is stored by the thermal battery 132 in boiler water contained by the boiler 132.

The boiler 132 is configured to heat potable water to produce domestic hot water. The boiler 132 includes a phase change material (PCM) configured to increase the amount of thermal energy stored by the boiler 132 per unit volume and thus provide substantially increased capacity to produce domestic hot water. The PCM enables the boiler 132 to operate at higher temperatures and within a smaller volume versus standard boilers configured to provide the same amount of domestic hot water that lack the PCM since the PCM supplements heat loss and instead supplies heat back to the boiler water of the boiler 132.

The thermoelectric converter 152 is configured to convert a portion of the thermal energy stored in the boiler 132 into electrical energy that is stored in the electric battery 150. The electric battery 150 is configured to provide power to the thermoelectric battery system 100 (e.g., to pumps of the thermoelectric battery system 100) or to peripheral domestic devices (e.g., a light fixture, a fan, a refrigerator, a cellphone charger, etc.).

In aspects, the boiler 132 of the thermal battery 130 includes a reverse indirect water heater tank (e.g., inner tank 134a described below) and a tank containing the PCM to increase the energy stored per unit volume of the boiler 132. A reverse indirect water heater tank, such as that described in U.S. Pat. No. 8,376,243 to Louis Cloutier, issued Feb. 19, 2013, the entire contents of which are herein incorporated by reference, operates by keeping boiler water (non-potable system water) in the tank hot and passing potable water through a heat exchanger to heat the potable water. In other aspects, the boiler 132 of the thermal battery 130 includes a heat exchanger with fluid injectors such as that described in U.S. Pat. No. 5,165,472 to Louis Cloutier, issued Nov. 24, 1992, the entire contents of which are herein incorporated by reference. The boiler water is in a first tank and the PCM is in a second tank surrounding the first tank, as described in detail below. Pipes carrying potable water are routed through the thermal battery 130 such that the potable water may be heated for domestic hot water use, hydronic heating, or hydronic cooling.

The thermoelectric battery system 100 is further configured to provide electricity to bridge the gap during a power outage, or, for example, when electricity costs are at their peak during the day. The boiler 132 of the thermal battery 130 is coupled to the thermoelectric converter 152 to convert heat stored in the thermal battery 130 into electrical energy to power pumps or other devices when electrical energy from a utility grid is unavailable or expensive. The electric battery 150 may be coupled to the thermal battery and be charged via the thermoelectric converter 152 or directly from the utility grid 10 when electricity is cheaper (e.g., at night during low demand). The electric battery 150 may be configured to operate as a standby emergency power source for powering various components of the thermoelectric battery system 100 (e.g., pumps) or powering peripheral devices (e.g., a fan if the weather is hot, a light fixture, etc.).

The thermoelectric battery system 100 may include a second thermal battery 130a or a plurality of thermal batteries. The second thermal battery 130a is configured similar to thermal battery 130. In aspects, the second thermal battery 130a may provide domestic hot water while thermal battery 130 provides hydronic heating, hydronic cooling, or electrical energy (or vice versa). The thermoelectric battery system 100 may include any number of thermal batteries 130 that may each be configured to supply domestic hot water, hydronic heating, hydronic cooling, electrical energy or any combination thereof. Each thermal battery 130 may be independently operable. For example, second thermal battery 130a may provide domestic hot water while thermal battery 130 may be ‘re-charging’ (e.g., storing new heat from the heat pump 110 for later use). In another example, both thermal battery 130 and second thermal battery 130a may each be simultaneously supplying domestic hot water and hydronic heating to a building.

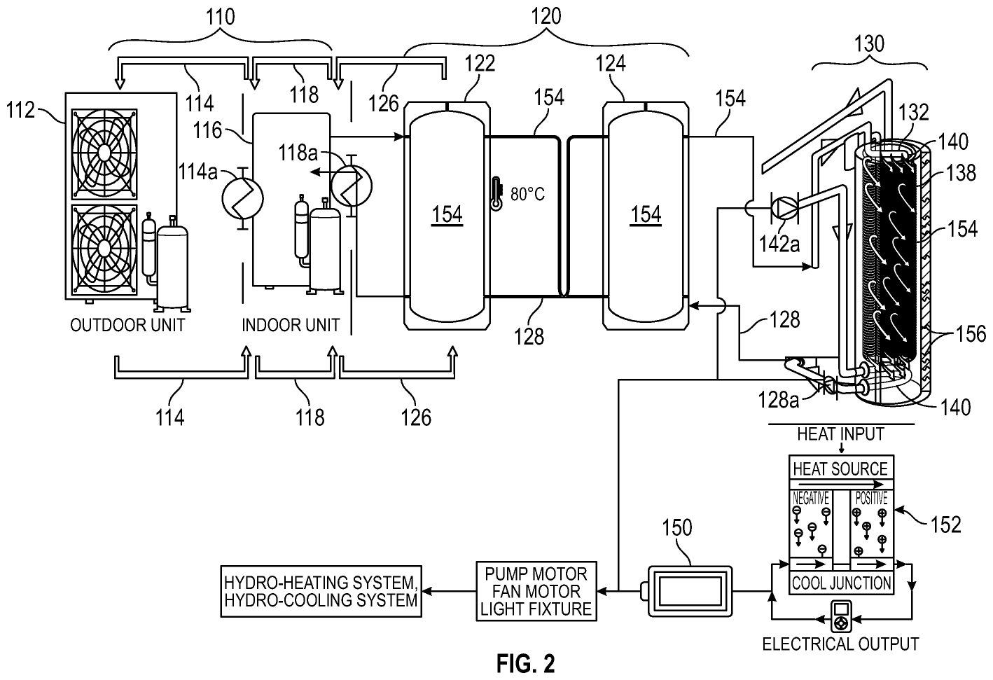

With reference to FIG. 2, the thermoelectric battery system 100 includes the heat pump 110, a buffer system 120, and the thermal battery 130. The heat pump 110 is thermally coupled to the buffer system 120 and the buffer system 120 is thermally coupled to the thermal battery. The buffer system 120 includes at least one buffer tank, such as, for example, first buffer tank 122. Components such as heat pump 110, buffer system 120, and thermal battery 130 may be connected with piping which may divide the overall system flow into equal streams with approximately equal flow resistance through each branch such as reverse return piping or piping including balancing valves.

The heat pump 110 is coupled to an electrical source 10 (FIG. 1) and is configured to generate heat. The heat pump 110 may be an air-to-air heat pump, an air-to-water heat pump, water source heat pump, a geothermal heat pump, a thermoelectric heat pump, or any similar heat pump. The heat pump 110 may include a first compressor 112 thermally coupled to a first thermal circuit 114. The first compressor 112 is thermally coupled to a second compressor 116 via the first thermal circuit 114. The second compressor 116 is thermally coupled to the buffer system 120 via a second thermal circuit 118. The second thermal circuit 118 thermally couples the first buffer tank 122 to the second compressor 116. In aspects, the first compressor 112 is located outside a building and the second compressor 116 is located inside the building. In aspects, the first compressor 112 is thermally coupled to the first buffer tank 122 via the first thermal circuit 114.

The first compressor 112 is configured to heat a first fluid in the first thermal circuit. In aspects, the first compressor 112 is configured to compress a first refrigerant circulating through the first thermal circuit 114 thereby heating the first refrigerant. The heat in the fluid (e.g., the first refrigerant) is circulated to the second compressor 116 via the first thermal circuit. The heat from the first refrigerant is transferred into a second refrigerant by a heat exchanger 114a of the first thermal circuit 114. The first and second refrigerants may be any suitable refrigerant known by those of ordinary skill in the art, such as R-410A or R-22, etc.

The second compressor 116 is configured to compress the second refrigerant flowing through the second thermal circuit 118 thereby raising the temperature of the second refrigerant. The second thermal circuit 118 includes a heat exchanger 118a to transfer heat from the second refrigerant to the boiler water contained by the first buffer tank 122. This enables the heat pump 110 to transfer heat from a low temperature source (e.g., air or a body of water) into a higher temperature fluid, such as boiler water 154 in the first buffer tank 122. In aspects, the first and second compressors 112, 116, and the first and second thermal circuits 114, 118, form a thermal double-lift cycle heat pump 110.

In aspects, a water heating circuit 126 couples the buffer system 120 to the second thermal circuit 118. The heat exchanger 118a is coupled to the water heating circuit 126 and configured to transfer heat from the second refrigerant to boiler water 154 flowing through the water heating circuit 126. First thermal circuit 114, second thermal circuit 118, and water heating circuit 126 may each include a pump (not shown) configured to circulate the fluid through the respective circuit. In aspects, the water heating circuit 126 may contain a water heater fluid, and the water heating circuit 126 includes a heat exchanger in the first buffer tank 122 to heat boiler water 154 contained therein.

The buffer system 120 is configured to store the heat generated by the heat pump 110 in a fluid, such as the boiler water 154. The boiler water 154 may be heated to between about 135° F. to about 175° F. or about 57° C. to about 80° C. The buffer system 120 includes one or more buffer tanks. The thermal battery system 100 illustrated in FIG. 2 includes first buffer tank 122 and a second buffer tank 124. Any number of buffer tanks may be included in the thermal battery system 100. Each buffer tank may contain between about 50 gallons to about 500 gallons of boiler water 154.

The first and second buffer tanks 122, 124, are in fluid communication with each other via a boiler water circuit 128, and therefore are thermally coupled to each other. In aspects, the first and second buffer tanks 122, 124 are thermally coupled to each other in series. First and second buffer tanks 122, 124 are coupled to each other such that thermal energy is evenly distributed between each tank so as to mitigate heat stratification between each tank and the thermal battery 130.

The first and second buffer tanks 122, 124 may be thermally coupled to the thermal battery 130 in series or in parallel. In aspects, when thermoelectric battery system 100 includes a plurality of thermal batteries 130, each buffer tank may be coupled to one or more thermal batteries 130 or a plurality of buffer tanks may be coupled to one or more thermal batteries of the plurality of thermal batteries 130. The boiler water circuit 128 couples the buffer system 120 to the one or more thermal batteries 130. The buffer system 120, via the first buffer tank or the second buffer tank, is configured to provide heat to the thermal battery 130 to operably maintain or increase the temperature of the boiler water 154 in the thermal battery 130. A pump 128a of the boiler water circuit is configured to cause the boiler water 154 to flow between the buffer system 120 and the thermal battery 130.

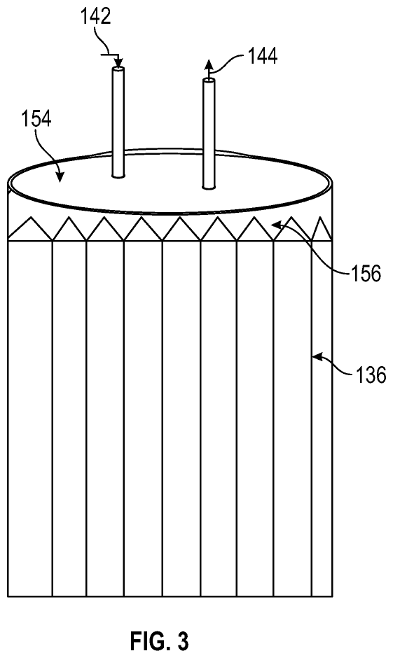

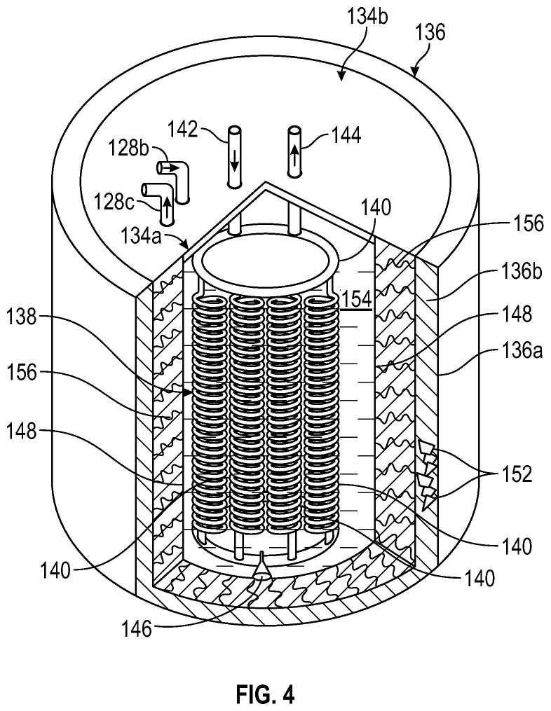

With additional reference to FIGS. 3 and 4, The thermal battery 130 is configured to receive heated boiler water 154 from the buffer system 120. The thermal battery 130 includes a boiler 132 defining an inner tank 134a containing boiler water 154 and an outer tank 134b containing the phase change material (PCM) 156. The boiler 132 also includes a heat exchanger 138 disposed in the inner tank 134a configured to enable potable water to flow therethrough to be heated by the boiler water 154 in the first inner tank 134a. A potable water inlet 142 is coupled to the heat exchanger 138 and is configured to enable potable water to flow through the heat exchanger 138 and out a potable water outlet 144. A pump 142a pumps potable water through the water inlet 142 and the heat exchanger 138. The potable water outlet 144 is connected to plumbing of a building (not shown) so as to provide domestic hot water, hydro-heating or hydro-cooling to the building.

Heat exchanger 138 includes an array of pipes 140 in fluid communication with the potable water inlet 142 and the potable water outlet 144. In aspects, the array of pipes 140 are a plurality of helical coils 140. In aspects, each helical coil of the plurality of helical coils 140 includes a portion thereof disposed between a portion of an adjacent helical coil so as to fit and allow for more helical coils inside the inner tank 134a or for helical coils to maintain the same surface to boiler water ratio in a smaller inner tank 134a. The array of pipes 140 of the heat exchanger 138 are configured so as to define a high coil surface area to boiler water ratio to enable the potable water flowing through the heat exchanger 138 to be heated to a desired temperature. The potable water may be heated within a temperature range between about 110° F. to about 125° F. to provide domestic hot water. It is contemplated that the potable water may be heated to higher or lower temperatures as desired (e.g., 135° F. or 105° F., respectively).

An insulative jacket 136 surrounds the outer tank 134b and is configured to insulate the inner and outer tanks 134a, 134b from the environment. The insulative jacket 136 may include a hard outer shell 136a that may be made of a metal (e.g., aluminum, tin, stainless steel, etc.) and includes an insulative material 136b that is at least one of open cell foam, closed cell foam, fiberglass, mineral wool, composite insulation, or any combination thereof. Any insulative material known by those of ordinary skill in the art may be used.

The boiler 132 may include an injector 146 configured to mix the boiler water 154 to evenly distribute a temperature profile in the boiler water 154 within the inner tank 134a. By mixing the boiler water 154 and maintaining an even temperature profile in the inner tank 134a, the longevity and efficiency of the boiler 132 is increased.

The outer tank 134b includes the phase change material PCM 156. The outer tank 134b is separated from the inner tank 134a by a thermally conductive wall 148 configured to enable the phase change material 156 to transfer heat between the inner and outer tanks 134a, 134b. The thermally conductive wall 148 may include a metal such as copper, aluminum, stainless steel, or brass. In aspects, the thermally conductive wall 148 is substantially made of copper. The thermally conductive wall 148 prevents the direct interaction or mixing between the phase change material PCM 156 and the boiler water 154. In aspects, the thermally conductive wall 148 is shared by the inner and outer tanks 134a, 134b such that thermally conductive wall 148 is an outer wall of the inner tank and an inner wall of the outer tank. The outer tank 134b is thereby configured to transfer heat to the inner tank 134a to maintain the thermal energy of the boiler water 154, supplement the thermal energy loss of the inner tank 134a due to the heat exchanger 138 heating potable water, or absorb excess thermal energy as the buffer system 120, via heat pump 110, heats the boiler water 154 back to maximum operating temperature (e.g., 175° F.).

The thermal battery 130 is operated between a fully thermally charged state and a partially thermally charged state. In the fully thermally charged state, the boiler water 154 in the inner tank 134a is at about 175° F. and the phase change material 156 in the outer tank 134b is at max capacity. The thermal battery 130 is in the partially thermally charged state when the boiler water 154 is below 175° F. As the heat exchanger 138 transfers heat from the boiler water 154 to the potable water flowing through the plurality of coils 140, the temperature, and therefore the thermal energy of the boiler water 154 drops, and the thermal battery 130 is in the partially thermally charged state. The thermal energy is lost by the boiler water 154 to the potable water to produce domestic hot water. The phase change material 156 supplies thermal energy to the boiler water 154 to maintain the boiler water 154 at or above 135° F. to about 175° F. It is contemplated that the phase change material 156 may supply thermal energy to the boiler water 154 to increase the temperature of the boiler water 154, for example, if the boiler water 154 temperature is below 135° F. (e.g., 110° F.).

Boiler water 154 from the first and second buffer tanks 122, 124 is pumped into the inner tank 134a via the pump 128a such that the thermal energy in the buffer system 120 and the thermal battery 130 are drawn down together. The inner tank 134a includes a boiler water inlet 128b and a boiler water outlet 128c that connects the inner tank 134a to the boiler water circuit 128. In aspects, by drawing down the thermal energy across the buffer system 120 and the thermal battery 130, heat stratification and stress on the thermoelectric battery system are reduced while also maintaining adequate production of domestic hot water.

The phase change material 156 may comprise at least one of paraffin wax, non-paraffin organic material, salt hydrates, or ice. In aspects, the phase change material 156 is paraffin wax due to its availability and more attractive cost. The phase change material 156 is configured to hold a larger amount of thermal energy per unit volume versus the boiler water 154.

As the thermal energy of the boiler water 154 and the phase change material 156 draws down, and the temperature of the boiler water 154 approaches 135° F., the heat pump 110 is operated to generate additional heat for the thermoelectric battery system 100. A sensor may be provided in the buffer system 120 or the thermal battery 130 to sense if the boiler water 154 is approaching 135° F. When the sensor determines that boiler water 154 is at or about 135° F., the heat pump 110 is then operated to generate additional heat. In aspects, the heat pump 110 generates heat for the thermoelectric battery system 100 until the thermal battery 130 reaches the fully thermally charged state. As heat is pumped into the inner tank 134a via the boiler water 154 from the buffer system 120, some of the heat is transferred from the boiler water 154 in the inner tank 134a to the PCM 156 in the outer tank 134b for later use.

A portion of the heat stored by the thermal battery 130 may be converted into electrical energy via the thermoelectric converter 152 of the thermal battery. The thermoelectric converter 152 is electrically coupled to an electric battery 150 and thermally coupled to the boiler 132. The thermoelectric converter 152 may comprise a plurality of thermopiles configured to convert thermal energy into electrical energy that are disposed inside the insulative jacket 136. The thermoelectric converter 152 may be in contact with the outer tank 134b or directly in contact with the PCM 156.

The electric battery 150 is a rechargeable battery and may be a lithium-ion battery, lead-acid battery, nickel-cadmium battery, nickel-metal hydride battery, a rechargeable alkaline battery or any combination thereof.

The electric battery 150 is configured to provide backup power to one or more pumps of the thermoelectric battery system 100, such as pump 128a or pump 142a. The electric battery 150 may be coupled to peripheral devices such as fans or light fixtures (e.g., emergency light fixtures) in a building to power the peripheral devices in a black out or when power from a utility grid is otherwise unavailable or expensive. The peripheral devices include cell phone chargers, refrigerators, safety devices (e.g., cameras, electronic door locks, fire safety systems), or pumps of a hydronic cooling system or a hydronic heating system.

In aspects, the thermoelectric converter may be directly electrically coupled to one or more pumps of the thermoelectric battery system 100, bypassing the battery 150. For example, if electrical energy in battery 150 is depleted, electrical energy may be supplied directly to pump 128a or a peripheral device. Hydraulic pumps (such as pumps 128a or 142a) require less energy to push a fluid through pipes, the amount of electrical energy needed from the electric battery 150 or thermoelectric battery 152 is minimal and the thermal battery 130 can thus bridge power outages or times where electricity is expensive.

It is contemplated that the thermoelectric battery system 100 could be configured to continue to provide domestic hot water, hydronic heating, hydronic cooling, or backup power for several hours (e.g., from about 2 hours to about 8 hours) to several days (e.g., from about 2 days to about 7 days). The amount of buffer tanks of buffer system 120 and the amount of thermal batteries 130 provided in the thermoelectric battery system 100 controls the capacity of domestic hot water that can be supplied or the amount of electrical energy that can be supplied or generated.

The size of each buffer tank and the size of each thermal battery further controls the capacity of domestic hot water, hydronic heating, hydronic cooling, or electrical energy the thermoelectric battery system 100 can supply. As described above, in one aspect, the buffer tanks may be configured to hold between about 50 gallons to about 500 gallons of boiler water 154. In other aspects, the buffer tanks may be configured to hold up to about 1,000 gallons of boiler water 154 or more. In one aspect, the inner tank 134a of the boiler 132 of the thermal battery 130 is configured to contain between about 50 gallons to about 500 gallons. In a particular example, the inner tank 134a may be configured to contain about 100 gallons of boiler water 154. In one aspect, the outer tank 134b may be configured to contain from about 20 gallons of PCM 156 to about 500 gallons of PCM 156. In other words, the amount of PCM 156 contained by the outer tank 134b may be larger or smaller than the actual amount of boiler water 154 contained in inner tank 134a.

As an illustrative example, in one aspect, the sizes of the inner and outer tanks are configured such that the maximum volume of PCM 156 can be calculated by equation 1:

$${V}_{PCM} = {π ( 1.25 * r )}^{2} ( 1.25 h ) - ( π {r}^{2} h ) \qquad ( equation 1 )$$

where V_{PCM} is the volume of the phase change material PCM 156, r is the radius of the inner tank, and h is the height of the inner tank.

The capacity of domestic water that can be produced by the thermoelectric battery system 100 thus varies greatly and can be tailored to different building needs. For example, a medium sized hotel with 50 guest rooms may use a thermoelectric battery system 100 having 4 buffer tanks configured to hold 300 gallons of boiler water 154 each, three thermal batteries 130 including 100-gallon inner tanks 134a and 200 gallon outer tanks 134b. In the prior example, the thermoelectric battery system 100 may provide up to 10,000 gallons of domestic hot water a day. Since the thermoelectric battery system 100 can be thermally charged when electrical generation is cheaper (or available), the hotel can still meet its demand for domestic hot water while saving money utilizing cheaper renewable energy that would otherwise not have been available when the domestic hot water needs to be produced. Any number of heat pumps 110 may be included in the thermoelectric battery system 100 to thermally charge the buffer system 120 and the thermal batteries 130. While the thermoelectric battery system 100 will lose some heat naturally, the thermoelectric battery system 100 is still more efficient at producing domestic hot water since it can store electrical energy when it is cheapest or available as thermal energy for later use without compromising the amount of domestic hot water produced versus conventional systems that rely on current time electrical generation or natural gas to produce domestic hot water.

In another example, a two-bedroom house may include a thermoelectric battery system 100 having a 100 gallon buffer tank and a 50 gallon inner tank 134a of thermal battery 130 and 75 gallons of PCM 156 in the outer tank 134b. The thermoelectric converter 152 ensures that the house may receive sufficient hydronic heating by converting the heat stored in the thermal battery 130 into electrical energy to operate the pumps of a hydronic heating system or the boiler water circuit 128, if, for example, there is a cold weather event and power generation is unavailable (which would otherwise cause electric heating systems or air-to-air heat pumps to fail since no power is available).

Although not shown, thermoelectric battery system 100 can be coupled to a hydronic heating system or hydronic cooling system. The pump 142a may pump heated water to a radiator system of a hydronic heating system. The radiator system is configured to radiate heat into a building. For example, the radiator system may be wall panel radiators or radiant heating systems. In aspects, heated water may be pumped to the thermal battery to store thermal energy therein in a hydronic cooling system. The hydronic cooling system may include chilled beam cooling devices, radiant panel cooling devices, radiant ceiling panels, radiant floor cooling, etc. Further details of hydronic heating and hydronic cooling systems are described in the Journal of Design Innovation for Hydronic and Plumbing Professionals by Caleffi Hydronic Solutions, Issue 28, titled Contemporary Hydronic Cooling for Commercial Buildings, published January 2021, the entire contents of which are herein incorporated by reference.

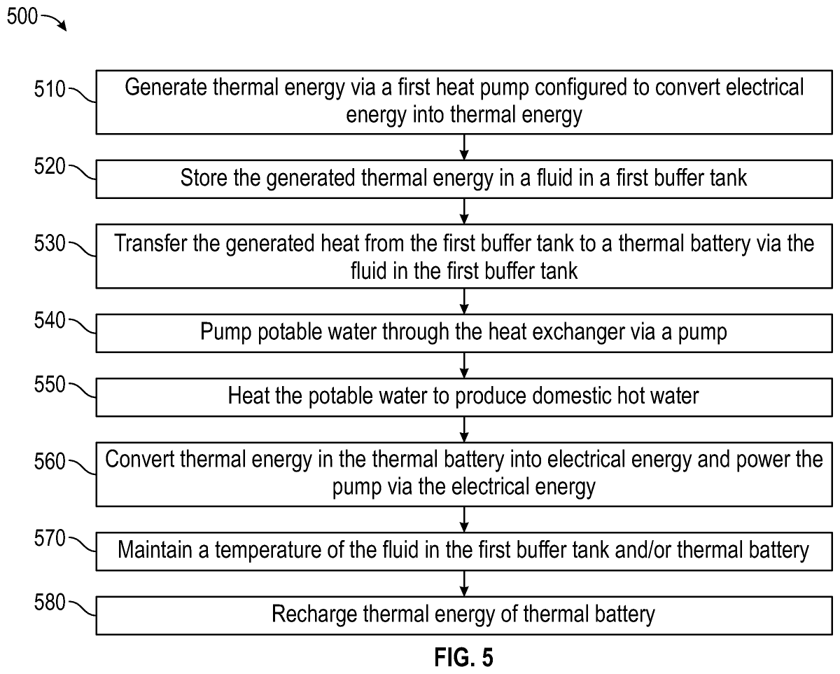

With reference to FIG. 5, this disclosure provides a method 500 for producing domestic hot water via a thermoelectric battery system 100. Operation 510 of the method includes generating thermal energy via the first heat pump 110. Operation 510 may include powering the first heat pump via an electrical energy source (e.g., an electrical grid, solar panel array, wind turbine). Operation 520 includes storing the generated thermal energy in a fluid (e.g., boiler water 154) in the first buffer tank 122 of the buffer system 120. Operation 530 of the method includes transferring the generated heat from the buffer tank 122 to the thermal batter 130 via the fluid in the first buffer tank 122. In aspects, operation 530 includes pumping the fluid via pump 128a through the boiler water circuit 128. Operation 540 includes pumping potable water, via pump 142a, through the heat exchanger 138 in the inner tank 134a of the boiler 132 of thermal battery 130. Operation 550 includes heating the potable water, via the heat exchanger 138, to produce domestic hot water. In aspects, operation 550 includes heating the potable water to a temperature between about 110° F. to about 125° F., although higher temperatures are contemplated.

The method 500 may include operation 560 which includes converting thermal energy in the thermal battery 130 into electrical energy via the thermoelectric converter 152. Operation 560 may further include powering the pump 128a or pump 142a via the electrical energy. Operation 560 may further include storing the electrical energy in an electric battery 150. Operation 570 of the method 500 includes maintaining a temperature of the fluid in the first buffer tank 122 or thermal battery 130. Operation 570 may include heating the fluid in the inner tank 134a via thermal energy stored in phase change material 156 contained in the outer tank 134b.

In aspects, operation 570 includes generating additional heat via heat pump 110. In aspects, the method includes operation 580 of recharging the thermal energy of the thermal battery. In aspects, operation 570 or operation 580 may be performed when the temperature of the fluid (e.g., the boiler water 154) is about 135° F. In aspects, operation 580 may be delayed until electrical energy generation from the electrical energy source is cheaper (e.g., during off peak demand times). In aspects, operation 580 is performed when renewable energy is readily available (e.g., when the wind is blowing thereby powering a wind turbine for generation of renewable energy).

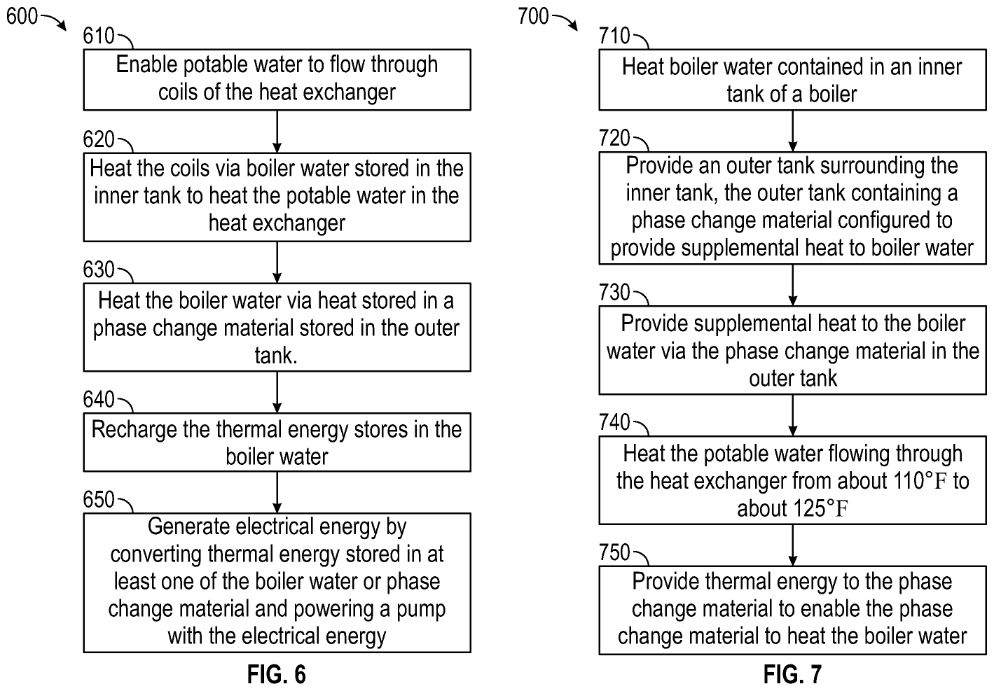

With reference to FIG. 6, a method 600 for providing domestic hot water via a thermoelectric battery (e.g., thermal battery 130 including the boiler 132 and electric battery 150) includes operation 610 enabling potable water to flow through the array of pipes 140 of the heat exchanger 138 in the inner tank 134a. Operation 620 includes heating the array of pipes 140 via the boiler water 154 in the inner tank 134a to heat potable water flowing through the array of coils 140. Operation 620 may include mixing the boiler water 154 via injector 146 to maintain an even temperature profile of the boiler water 154 for evenly heating the array of pipes 140. In aspects, operation 620 further includes injecting boiler water 154 from the buffer system 120 to mix the boiler water 154. In further aspects, in operation 620, the injector 146 injects boiler water 154 so as to cause the boiler water 154 to flow in a direction opposite the flow of potable water in the heat exchanger 138. Operation 630 includes heating the boiler water 154 in the inner tank 134a via heat stored in the phase change material 156 in the outer tank 134b. In aspects, an operation 640 includes recharging the thermal energy stored in the boiler water 154 or the PCM 156 (via the boiler water 154) via thermal energy from the heat pump 110. Operation 640 includes supplying heat to at least one of the boiler water 154 or the phase change material 156 via the heat pump 110. Operation 650 includes generating electrical energy by converting thermal energy stored in at least one of the boiler water 154 or PCM 156 and powering a pump (e.g., pumps 128a, or 142a, or a pump of a hydronic heating or cooling system) via the electrical energy. In aspects, operation 650 may include powering a peripheral device (e.g., a light fixture).

With reference to FIG. 7, a method 700 for heating water for domestic use is illustrated. Operation 710 includes heating boiler water 154 contained in an inner tank 134a of a boiler 132. Operation 720 includes providing an outer tank 134b surrounding the inner tank 134a. Operation 730 includes providing supplemental heat to the boiler water 154 in the inner tank 134a. Operation 740 includes heating potable water flowing through a heat exchanger 138 disposed in the inner tank 134a. Operation 740 may include heating the potable water to between about 110° F. to about 125° F. Operation 750 includes providing thermal energy to the PCM 156 to enable the PCM 156 to heat the boiler water 154. The thermal energy may be provided by charging the boiler water 154 with thermal energy when the thermoelectric battery system 100 does not need to produce domestic hot water or when the thermoelectric battery 100 is not operating at full domestic hot water production capacity (e.g., during off peak demand for domestic hot water).

Although various operations of the methods 500, 600, and 700 are presented in a particular sequence, such operations or portions of operations can be implemented in a different sequence than as described or illustrated herein. Additionally, various operations or portions of operations can be implemented concurrently or simultaneously. Portions of one or more operations can be implemented in one or more other operations and/or can be implemented differently than as illustrated or described. The illustrations and descriptions herein may describe operations that utilize a thermoelectric battery system 100 of this disclosure but is not limited to the particular configurations of the thermoelectric battery system 100 described above. It is contemplated that the operations can be applied sequentially, concurrently, or simultaneously to more than one thermoelectric battery system 100. The operations described herein can be implemented by a controller having a processor and a memory with instructions for executing the operations.

The phrases “in an aspect/embodiment,” “in aspects/embodiments,” “in various aspects/embodiments,” “in some aspects/embodiments,” or “in other aspects/embodiments” may each refer to one or more of the same or different aspects/embodiments in accordance with the present disclosure. A phrase in the form “A or B” means “(A), (B), or (A and B).” A phrase in the form “at least one of A, B, or C” means “(A); (B); (C); (A and B); (A and C); (B and C); or (A, B, and C).”

While several embodiments of the disclosure have been shown in the drawings, it is not intended that the disclosure be limited thereto, as it is intended that the disclosure be as broad in scope as the art will allow and that the specification be read likewise. Therefore, the above description should not be construed as limiting, but merely as examples of particular embodiments. Those skilled in the art will envision other modifications within the scope and spirit of the claims appended hereto.

What is claimed is:

1. A thermoelectric battery configured to provide at least one of hot water for domestic use, hydro-heating, or hydro-cooling, comprising:
an inner tank configured to contain boiler water for storing and providing heat;
an outer tank surrounding the inner tank and separated therefrom by a thermally conductive wall, the outer tank configured to contain a phase-change material to supply heat to the inner tank;
a heat exchanger disposed in the inner tank configured to enable domestic water to flow therethrough to enable potable water to be heated by boiler water; and
an electric battery coupled to a thermoelectric converter, the thermoelectric converter configured to convert heat stored in the inner tank into electricity to be stored by the electric battery.

2. The thermoelectric battery of claim 1, wherein the thermoelectric converter includes at least one thermopile.

3. The thermoelectric battery of claim 1, wherein the electric battery is configured to provide backup power to at least one of a pump, an appliance, a light fixture, or a fan.

4. The thermoelectric battery of claim 1, wherein the electric battery comprises at least one of lithium ion, nickel-cadmium, zinc-air battery, or nickel metal hydride.

5. The thermoelectric battery of claim 1, wherein the heat exchanger further comprises a plurality of coils disposed in the inner tank configured to circulate the potable water therethrough.

6. The thermoelectric battery of claim 5, wherein the plurality of coils define a high coil surface area to boiler water ratio.

7. The thermoelectric battery of claim 5, wherein the plurality of coils are disposed only in the inner tank of the thermal battery.

8. The thermoelectric battery of claim 5, wherein the plurality of coils disposed in the inner tank are helical coils.

9. The thermoelectric battery of claim 1, wherein the inner tank is further configured as a reverse indirect water heater tank.

10. The thermoelectric battery of claim 1, further comprising an insulative jacket configured to cover the outer tank to insulate the outer and inner tanks.

11. The thermoelectric battery of claim 10, wherein the insulative jacket comprises at least one of closed cell foam, open cell foam, fiberglass, mineral wool, or composite insulation.

12. The thermoelectric battery of claim 1, wherein the outer tank is further configured to absorb excess heat from the inner tank.

13. The thermoelectric battery of claim 11, wherein the outer tank is configured to operably increase or maintain the boiler water contained in the inner tank between a temperature from about 125° F. to about 175° F.

14. The thermoelectric battery of claim 1, wherein the outer tank is configured to operably increase or maintain the boiler water contained in the inner tank between a temperature from about 125° F. to about 175° F.

15. The thermoelectric battery of claim 1, wherein the thermally conductive wall comprises at least one of copper, aluminum, stainless steel, or brass.

16. The thermoelectric battery of claim 1, wherein the phase-change material comprises at least one of paraffin wax, non-paraffin organic material, salt hydrates, or ice.

17. A thermoelectric battery system, comprising:
a first heat pump configured to generate heat;
a first buffer tank thermally coupled to the first heat pump, the first buffer tank configured to store the generated heat in boiler water;
a first thermal battery thermally coupled to the first buffer tank, the first thermal battery configured to provide at least one of hot water for domestic use, hydro-heating, or hydro-cooling, the first thermal battery comprising:
an inner tank configured to contain a first portion of a quantity of boiler water for storing and providing heat;
an outer tank containing a phase change material, the outer tank surrounding the inner tank and separated therefrom by a thermally conductive wall, the outer tank configured to supply heat to the inner tank; and
a heat exchanger disposed in the inner tank configured to enable domestic water to flow therethrough to enable the domestic water to be heated by boiler water;
an electric battery electrically coupled to a thermoelectric converter, the thermoelectric converter configured to convert heat in the first thermal battery into electricity; and
a pump configured to supply water to the heat exchanger and pump water to a building for domestic use.

18. The thermoelectric battery system of claim 17, wherein the first thermal battery further includes an insulative jacket configured to cover the outer tank to insulate the outer and inner tanks

19. The thermoelectric battery system of claim 18, wherein the phase-change material comprises at least one of paraffin wax, non-paraffin organic material, salt hydrates, or ice.

20. The thermoelectric battery system of claim 17, wherein the electric battery is configured to provide backup power to the pump.

21. The thermoelectric battery system of claim 17, wherein the first heat pump includes a first compressor having a first thermal circuit configured to supply heat to a first refrigerant.

22. The thermoelectric battery system of claim 21, wherein the first thermal circuit is configured to thermally couple the first compressor and the first buffer tank to supply heat to the first buffer tank.

23. The thermoelectric battery system of claim 22, wherein the first heat pump further includes a second compressor including a second thermal circuit configured to transfer heat from the first refrigerant to a second refrigerant of a second thermal circuit.

24. The thermoelectric battery system of claim 23, wherein the first compressor is thermally coupled to the second compressor via the first thermal circuit and the first buffer tank is coupled to the first compressor via the second thermal circuit of the second compressor.

25. The thermoelectric battery system of claim 24, wherein the first compressor is configured to be located outdoors and the second compressor is configured to be located indoors.

26. The thermoelectric battery system of claim 17, further comprising a plurality of buffer tanks including the first buffer tank and a second buffer tank, each buffer tank of the plurality of buffer tanks are thermally coupled in series.

27. The thermoelectric battery system of claim 26, further comprising a plurality of thermal batteries including the first thermal battery and a second thermal battery, wherein each thermal battery is thermally coupled in series with the plurality of buffer tanks.

28. The thermoelectric battery system of claim 17, further comprising a plurality of thermal batteries including the first thermal battery and a second thermal battery, wherein each thermal battery is connected in series.

29. The thermoelectric battery system of claim 17, wherein the thermal battery is configured to operably increase or maintain boiler water contained in the inner tank between a temperature from about 135° F. to about 175° F.

30. The thermoelectric battery system of claim 29, wherein the first buffer tank is configured to provide heat to the thermal battery to enable the thermal battery to operably maintain or increase the temperature of the boiler water.

31. The thermoelectric battery system of claim 17, wherein the first buffer tank is configured to provide heat to the thermal battery to enable the thermal battery to operably maintain or increase the temperature of the boiler water.

32. The thermoelectric battery system of claim 17, wherein the heat exchanger is configured to heat the domestic water to between about 110° F. to about 135° F.

33. The thermoelectric battery system of claim 17, wherein the first heat pump is connected to the first buffer tank, or the first buffer tank is connected to the first thermal battery by reverse return piping or piping including balancing valves.

34. A method for providing domestic hot water comprising:
generating heat via a first heat pump configured to convert electrical energy into heat;
storing the generated heat in a fluid in a first buffer tank;
transferring the generated heat from the first buffer tank to a thermal battery via the fluid in the first buffer tank, the thermal battery comprising:
an inner tank configured to contain boiler water for storing a first portion of the generated heat therein;
an outer tank surrounding the inner tank and separated therefrom by a thermally conductive wall, the outer tank configured to contain a phase change material for storing a second portion of the generated heat therein; and
a heat exchanger disposed in the inner tank;
pumping potable water through the heat exchanger via a pump; and
heating the potable water to produce domestic hot water.

35. The method of claim 34, further comprising converting thermal energy in the thermal battery into electrical energy via a thermoelectric converter; and
powering the pump via the electrical energy.

36. The method of claim 34, further comprising heating the boiler water in the inner tank via heat stored in the phase change material contained in the outer tank.

37. The method of claim 36, further comprising maintaining the boiler water between about 135° F. to about 175° F.

38. A method for providing domestic hot water via a thermoelectric battery comprising an inner tank, an outer tank, a heat exchanger disposed in the inner tank, and a thermoelectric converter, the method comprising:
enabling potable water to flow through coils of the heat exchanger;
heating the coils via boiler water stored in the inner tank to heat the potable water in the heat exchanger; and
heating the boiler water via heat stored in a phase change material stored in the outer tank.

39. The method of claim 38, further comprising generating electrical energy by converting thermal energy stored in at least one of the boiler water of the inner tank or the phase change material of the outer tank.

40. The method of claim 39, further comprising powering a pump via the generated electrical energy.

41. The method of claim 38, further comprising supplying thermal energy to at least one of the boiler water or the phase change material via a heat pump configured to convert electrical energy from a source of electricity into thermal energy.
